(19) United States
(12) Patent Application Publication
(10) Pub. No.: US 2012/0047994 A1
(43) Pub. Date: Mar. 1, 2012

(54) NITROGEN GAS SENSOR AND ITS MANUFACTURING METHOD

(76) Inventors: Chi-Yen Shen, Kaohsiung County (TW); Shih-Han Wang, Kaohsiung County (TW)

(21) Appl. No.: 12/942,845

(22) Filed: Nov. 9, 2010

(30) Foreign Application Priority Data
Aug. 25, 2010 (TW) 099128428

(51) Int. Cl. G01N 29/02; H01L 41/22

(52) U.S. Cl. 73/24.06; 29/25.35

(57) ABSTRACT

A nitrogenous gas sensor comprises a piezoelectricity plate which has a sensing surface; two transducers placed on the sensing surface of the piezoelectricity plate for transduction of electrostatic potential energy and acoustic energy, in order to generate surface acoustic waves on the piezoelectricity plate; and a sensing layer installed on the sensing surface of the piezoelectricity plate between the two transducers, which is consisted of polyaniline and tungsten oxide. Furthermore, a manufacturing method of the nitrogenous gas sensor comprises a step of “manufacturing transducer,” by placing two transducers on the sensing surface of the piezoelectric plate; and a step of “manufacturing sensing layer,” by mixing a solution of polyaniline and a solution of tungsten oxide to obtain a mixture of polyaniline and tungsten oxide, and further generating a sensing layer consisted of nano-scaled of complex polyaniline and tungsten oxide between the two transducer by dropping the mixture of polyaniline and tungsten oxide on the sensing surface of the piezoelectric plate.

### BACKGROUND OF THE INVENTION

1. Field of the Invention

The present invention relates to a gas sensor and its manufacturing method, particularly to a nitrogenous gas sensor and its manufacturing method.

2. Description of the Related Art

Hazardous gases, mostly related to manufacturing facilities, motor vehicles, waste incinerators or other types of fuel-burning factories, are widely distributed everywhere. It is suggested that these hazardous gases are damaging to the natural environment and living organisms; therefore, an effective gas sensor may be necessary to people nowadays for avoiding the poison from the hazardous gases.

Generally, the gas sensors are gas detectors that measure the content and concentration of target gases in the environment, and can be divided into several types such as electrochemical gas sensor, solid-state electrolyte based gas sensor and electronic gas sensor. The electrochemical gas sensor operates by oxidizing or reducing the target gases at a liquid electrolyte, and measuring the resulting voltage or current to obtain the content and concentration of target gases. However, the liquid electrolyte may easily lead to the erosion of the gas sensor, causing the service life of the electrochemical gas sensor to be short.

On the other hand, the solid-state electrolyte based gas sensor is mainly associated with the principle of concentration cell. This involves measuring a physical property changed of the solid-state electrodes by the adsorption/desorption processes of target gases on the surface of a sensing element, and analyzing the concentration of the target gases. Therefore, the disadvantages caused by the liquid electrolyte, such as corrosion and spouting, no longer occur.

The electronic gas sensor, usually considered as convenient and popular, is mainly dependent upon sensing materials, including metal oxides (for example Al₂O₃; TiO), polymer of metal phthalocyanine (for example CuPc) or piezoelectric materials (for example SiO₂), to adhere to and detect target gases. In this situation, the concentration of the target gases is obtained by analyzing either the difference of conductive rate or the mass difference on the sensing materials due to the adhesion of target gases.

Nevertheless, owing to the poor sensitivity of general sensing materials at lower temperature, the processes of the solid-state electrolyte based gas sensor and of the electronic gas sensor might be less efficient at room temperature. Accordingly, an additional heating plate is necessary for providing high temperature (around >200° C.) to the sensing materials in the solid-state electrolyte based gas sensor and the electronic gas sensor; for example, the metal oxide needs to be processed at approximately >150° C., and the metal phthalocyanine needs about 165° C. while processing. This not only brings about more inconvenience, but also increases cost and the consumption of energy.

As disclosed in Taiwanese patent 1295038, a nitric oxide gas sensor comprises a piezoelectric plate, a sensing layer of polymer, a pair of transducers (including an inlet transducer and an outlet transducer) and a pair of acoustic reflectors, wherein the piezoelectric plate contains a sensing surface, with the sensing layer of polymer covered with an amide group generated on it. The two transducers and two acoustic reflectors are installed separately on the sensing surface of the piezoelectric plate, wherein the two acoustic reflectors are sited on the two lateral edges of the piezoelectric plate, with the two transducers sandwiched in between the two acoustic reflectors and the sensing layer of polymer respectively.

In the detection, with a voltage inputted from the inlet transducer, the piezoelectric plate will immediately vibrate and transduce electrostatic potential energy into acoustic energy via the reverse currents of the piezoelectric plate so as to create surface acoustic waves on the surface of the piezoelectric plate. In the mean time, nitric oxide will adhere and interact with the surface of the sensing layer of polymer where the mass of the sensing layer of polymer may increase, leading to the change in frequency of the surface acoustic waves. In this way, the concentration of the nitric oxide can be determined by analyzing the electrostatic potential energy transduced from the surface acoustic waves of the sensing layer.

However, the weakness of the machine strength relating to the single sensing material results in the poor tolerance of the environment and climate by the above nitric oxide gas sensor, which may easily incur the distortion, chapping and deterioration of the sensing layer. Moreover, the multi-porous structure of the single sensing material shows poor adhesion to target gases other than at the partition of the multi-porous structure, so as to be time-consuming and inefficient in detection.

Consequently, regarding the disadvantages of the above gas sensor, there is a need to improve the device of the gas sensor, as well as its manufacturing method.

### SUMMARY OF THE INVENTION

The primary objective of this invention is to provide a nitrogenous gas sensor which can be effectively operated at room temperature so as to be dramatically convenient.

The secondary objective of this invention is to provide a nitrogenous gas sensor, in which a sensing layer is made of a complex material so that the machine strength and environmental tolerance are intensified.

Another objective of this invention is to provide a nitrogenous gas sensor, in which the contact surfaces between the sensing layer and target gases are significantly increased so as to be highly sensitive to nitrogen.

Another objective of this invention is to provide a manufacturing method of the nitrogenous gas sensor that can successfully produce the nitrogenous gas sensor described above.

A nitrogenous gas sensor comprises a piezoelectricity plate which has a sensing surface; two transducers placed on the sensing surface of the piezoelectricity plate for transduction of electrostatic potential energy and acoustic energy, in order to generate surface acoustic waves on the piezoelectricity plate; and a sensing layer consisting of polyaniline and tungsten oxide installed on the sensing surface of the piezoelectricity plate between the two transducers.

Furthermore, a manufacturing method of the nitrogenous gas sensor comprises a step of “manufacturing transducer,” by placing two transducers on the sensing surface of the piezoelectric plate; and a step of “manufacturing sensing layer,” by mixing a solution of polyaniline and a solution of tungsten oxide to obtain a mixture of polyaniline and tungsten oxide, and further generating a sensing layer consisting of nano-scaled of complex polyaniline and tungsten oxide between the two transducers by dropping the mixture of polyaniline and tungsten oxide on the sensing surface of the piezoelectric plate.

Further scope of the applicability of the present invention will become apparent from the detailed description given hereinafter. However, it should be understood that the detailed description and specific examples, while indicating preferable embodiments of the invention, are given by way of illustration only, since various more will become apparent from this detailed description to those skilled in the art.

### BRIEF DESCRIPTION OF THE DRAWINGS

The present invention will become more fully understood from the detailed description given hereinbelow and the accompanying drawings which are given by way of illustration only, and thus are not limitative of the present invention, and wherein:

FIG. 1 is an analysis data of the composition of the sensor layer in the present invention;

FIG. 2 is a cubic diagram illustrating a nitrogenous gas sensor in accordance with a first embodiment of the present invention;

FIG. 3 is a top view of the nitrogenous gas sensor in accordance with a second embodiment of the present invention;

FIG. 4 is a top view of the nitrogenous gas sensor in accordance with a third embodiment of the present invention;

FIG. 5 is a schema illustrating a complex detection program of nitric oxide in the present invention;

FIG. 6 is a line chart illustrating the analysis data of the complex detection program in a repeated on-off test;

FIG. 7 is a line chart illustrating the analysis data of the complex detection program in another repeated on-off test;

FIG. 8 is a line chart illustrating the standard curve of the nitrogenous gas sensor in the present invention;

FIG. 9 is a diagram illustrating the responded time of the nitrogenous gas sensor in the present invention;

FIG. 10 is a diagram illustrating the recovery time of the nitrogenous gas sensor in the present invention;

FIG. 11 is a FE-SEM picture showing the multi-porous structure of the sensor layer in the present invention;

In the various figures of the drawings, the same numerals designate the same or similar parts. Furthermore, when the term “inner,” “outer,” “first,” “second,” “third,” “fourth,” “fifth,” “sixth,” “seventh,” “eighth,” “top,” and similar terms are used hereinafter, it should be understood that these terms are reference only to the structure shown in the drawings as it would appear to a person viewing the drawings and are utilized only to facilitate describing the invention.

### DETAILED DESCRIPTION OF THE INVENTION

In the present invention, a manufacturing method of the nitrogenous gas sensor comprises a step of “manufacturing transducers S1” and a step of “manufacturing sensing layer S2”.

In the step of “manufacturing transducers S1,” two transducers are placed on a piezoelectric plate, more precisely via a method of sintering, sedimentation or sputtering.

In the step of “manufacturing sensing layer S2,” a solution of polyaniline and a solution of tungsten oxide are mixed to obtain a mixture of polyaniline and tungsten oxide. Then, the mixture of polyaniline and tungsten oxide is dropped on the piezoelectric plate between the two transducers to generate a sensing layer.

In the embodiment of the present invention, the step of “manufacturing sensing layer S2” further comprises a step of “gelling S21” and a step of “polymerization S22,” wherein the step of “gelling S21,” an oxidation of tungsten hexachloride (also known as WCl₆) is processed to obtain gelatinous tungsten oxide. Precisely, the gelatinous tungsten oxide is precipitated and collected by mixing up the tungsten hexachloride with isopropanol (also known as CH₃CH₂CH₂OH) in an ice bath, followed by adding ammonium hydroxide (also known as NH₄OH) into the tungsten hexachloride and isopropanol to hydrolyze the tungsten hexachloride, and finally by washing out the chlorine with de-ionized water. In summary, details of the chemical reaction in the step of “gelling S21” are shown in Reaction 1.

WCl₆+ROH→W(OHR)ₓCl₍₆₋ₓ₎+HCl Reaction 1

In the step of “polymerization S22,” an oxidative polymerization of aniline is processed in an acidic environment to produce polyaniline, wherein an oxidant like (NH4)₂S₂O₈, KIO₃, FeCl₃ or K₂Cr₂O₇ is used in the oxidative polymerization and an organic acid or inorganic acid is added to perform as the acidic environment. As an example, hydrochloride acid (HCl) is used in the present invention as the addition to the acidic environment during the oxidative polymerization of aniline. Reaction 2 summarizes the chemical reactions in the step of “polymerization S22” of the present invention.

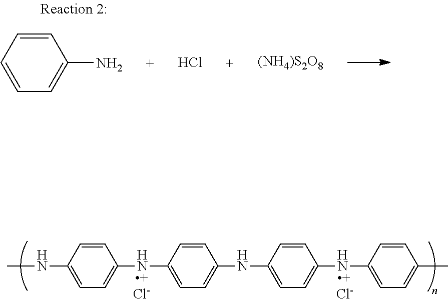

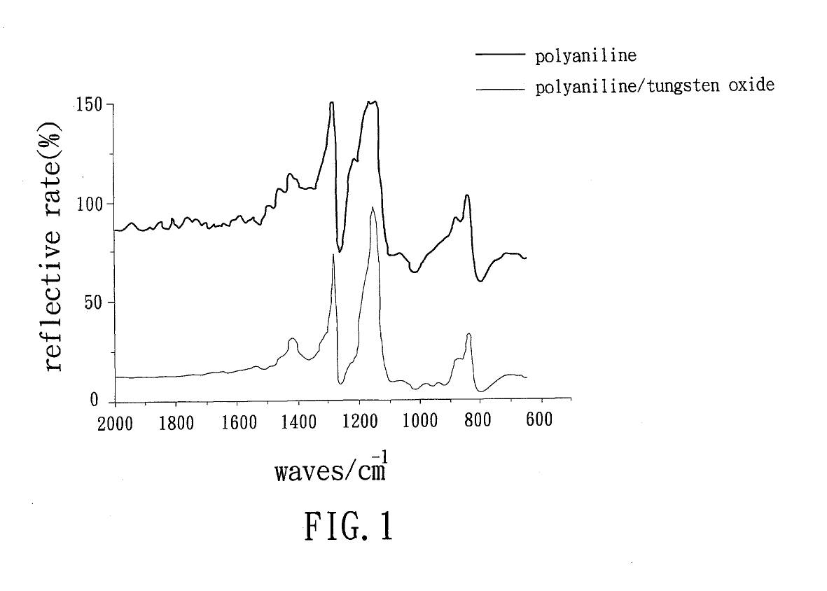

With reference to FIG. 1, it is proved that the sensing layer is consisted of a complex membrane of polyaniline and tungsten oxide, which shows signals at 750 cm⁻¹, as well as 1414 cm⁻¹ due to the resonance of tungsten oxide and hydroxyl band in a Fourier transform infrared spectroscopy (FTIR).

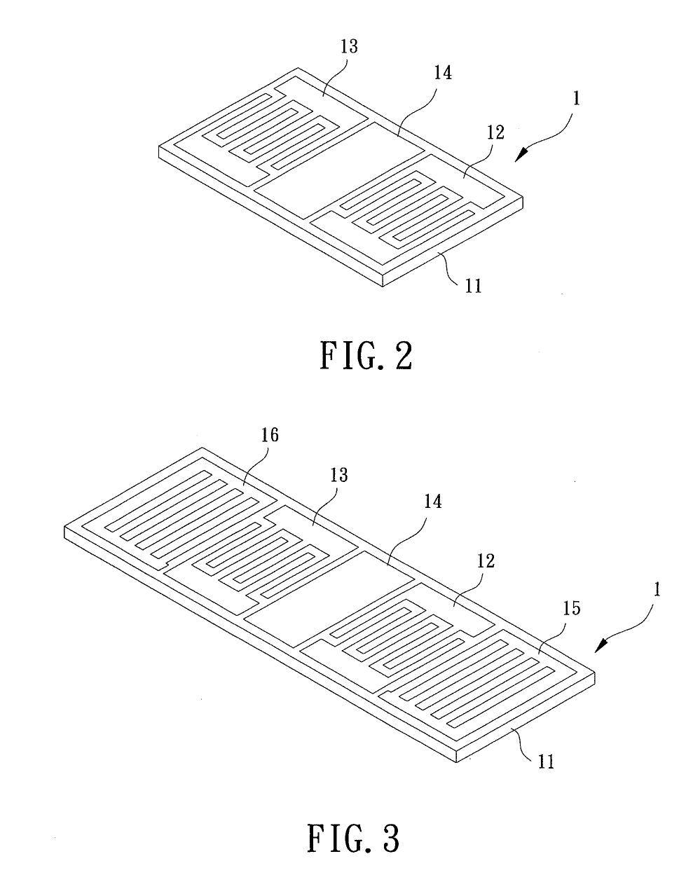

Referring to FIG. 2, in accordance with a first embodiment of the present invention, the nitrogenous gas sensor 1 includes a piezoelectric plate 11, an inlet transducer 12, an outlet transducer 13 and a sensing layer 14, wherein the piezoelectric plate 11 contains a sensing surface with the two transducers 12, 13 formed separately on it. Between the two transducers 12, 13, there is an inter-distance where the sensing layer 14 is installed. By contrast, the two transducers 12, 13 have a relative height to the piezoelectric plate 11, which is aligned to the essential voltage of the nitrogenous gas sensor. For example, the relative height of the two transducers 12, 13 is 300 nm in the preferable embodiment of the present invention, but is not be limited to that in the actual practice.

The piezoelectric plate 11 is made of a material that is stable under high temperature, such as quartz, LiTaO₃, LiNbO₃ or ZnO. In the embodiment of the present invention, a quartz plate is preferably used.

The two transducers 12, 13 are made of a highly electric conductive material, for example Au, Al, Cu and Pt. In the embodiment of the present invention, interdigital transducers with aluminum electrode are selected as the two transducers 12, 13. Furthermore, electrodes of the two transducers 12, 13 are staggered with one another, preferably covering with a layer of polyimide in order to create a protection on the electrode. Through the transduction of the electrostatic potential energy and acoustic energy between the two transducers 12, 13, surface acoustic waves are produced and further transmitted on the piezoelectricity plate 11.

The sensing layer 14 is installed on the surface of the piezoelectricity plate 11 via a dropwise method. The sensing layer 14 consists of a metal sensitive material, a metalline semiconductor, a conductive polymer or a complex of the above-listed. In the present invention, the sensing layer 14 is made of a complex of conductive polymer and metal oxide, wherein the conductive polymer can be polyaniline, polypyrrole or polythiophene, and the metal oxide can be tungsten oxide, silicon oxide or titanium oxide for the sake of enhancing the adhesion of the sensing layer 14 to nitrogenous gas. In the preferable embodiment of the present invention, the sensing layer 14 consists of a complex membrane of polyaniline and tungsten oxide, wherein the ratio between the polyaniline and tungsten oxide is 0.5 to 3, particularly 2.5. In this way, due to the multi-porous structure of the polyaniline, the contact surface between the polyaniline and gas can be enlarged, which may advance the adhesion of polyaniline to gas. Also, according to the compatibility between the polyaniline and the tungsten oxide, the tungsten oxide will be stuffed into the nano-scaled pores of the polyaniline to perform as a complex membrane of the tungsten oxide and the polyaniline. As a result, the contact surface with gases, as well as the adhesion of the sensing layer 14 to gases, can be dramatically enhanced in the nitrogenous gas sensor of the present invention.

Referring to FIG. 11, the multi-porous structure of the sensing layer is observed under a field emission scanning electron microscope (FE-SEM).

With reference to FIG. 3, in accordance with the second embodiment of the present invention, comparing with the first embodiment the sensor of the nitrogenous gas 1 further comprises two acoustic reflectors 15, 16 installed on the sensing surface of the piezoelectric plate 11, wherein the two acoustic reflectors 15, 16 are adjacent to the two lateral edges of the piezoelectric plate 11 respectively, with the two transducers 12, 13 sited beside. The two acoustic reflectors 15, 16 can be gratings, in order to avoid the loss of the surface acoustic waves and also advance the accuracy of the sensor. Furthermore, in the preferable embodiment of the present invention, the acoustic reflector 15, 16 are covered with a layer of polyimdie for providing a protection of the electrodes.

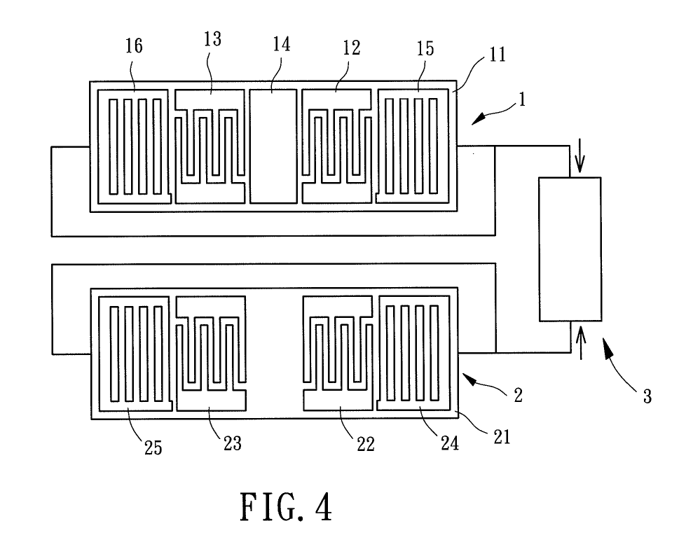

Referring to the FIG. 4, in accordance with the third embodiment of the present invention, the nitrogenous gas sensor 1 is further linked with a referable sensor 2 via a counter 3. The referable sensor 2 comprises a piezoelectric plate 21, an inlet transducer 22 and an outlet transducer 23, and two acoustic reflectors 24, wherein the configuration of the piezoelectric plate 21 is the same as the piezoelectric plate 11 of the nitrogenous gas sensor 11, except for the sensing layer 14. In this way, the nitrogenous gas sensor 1 of the present invention will be processed based on a behavior of Rayleigh surface acoustic waves (RSAW).

In the embodiment of the present invention, with the alternating currents inputted from the inlet transducer 12 of the nitrogenous gas sensor 1 and the inlet transducer 22 of the referable sensor 2, an electric field will be generated between the electrons of the inlet and outlet transducers 12, 13 of the nitrogenous gas sensor 1, and another electric field will also be generated between the electrons of inlet and outlet transducers 22, 23. In this situation, due to the reverse currents of the piezoelectric plate 11, the piezoelectric plate 11 will immediately vibrate and transduce electrostatic potential energy into acoustic energy so as to form a surface acoustic wave w on the surface of the piezoelectric plate 11, with a frequency of f. Similarly, the piezoelectric plate 21 will also transduce electrostatic potential energy into acoustic energy to form another surface acoustic wave w on the surface of the piezoelectric plate 21 with a frequency of f₀. In contrast to the referable value, f₀, the surface acoustic wave of f will lead to the vibrations on the sensing layer 14 in the nitrogenous gas sensor 1. However, while the nitrogenous gas adheres and interacts with the sensing layer 14, the mass loading effect of the sensing layer 14 will interfere with the original surface acoustic wave of f, finally generating another surface acoustic wave w1, with a frequency of f′. Then, the surface acoustic wave of f′ will be re-transduced to electrostatic potential energy via the outlet transducer 13, and further transmitted to the counter 3 for data analysis. In the meantime, the surface acoustic wave of f₀, the referable value, will also be re-transduced to electrostatic potential energy and analyzed at the counter 3.

Furthermore, the feedback reflections of the two acoustic reflectors 15, 16 on the nitrogenous gas sensor 1 will bring about the surface acoustic wave loss from the two transducers 12, 13 for the sake of preventing the energy loss and also improving the accuracy of the sensor. Correspondingly, the two reflectors 25, 26 on the referable sensor 2 will also bring about the lost surface acoustic waves from the two transducers 22, 23 so as to promote the accuracy of the sensor. In this situation, the interferences might also include the mass loading effect, acoustoelectric effect and elastic effect, which are involved in the operation of the gas sensor in the present invention. Therefore, in concern of the errors caused by above effects, an accurate value of the nitrogenous gas adhering to the nitrogenous gas sensor 1 can be estimated through the calculation of the frequency rate (Δf) between the surface acoustic waves of f′ and f₀ with some relative equations.

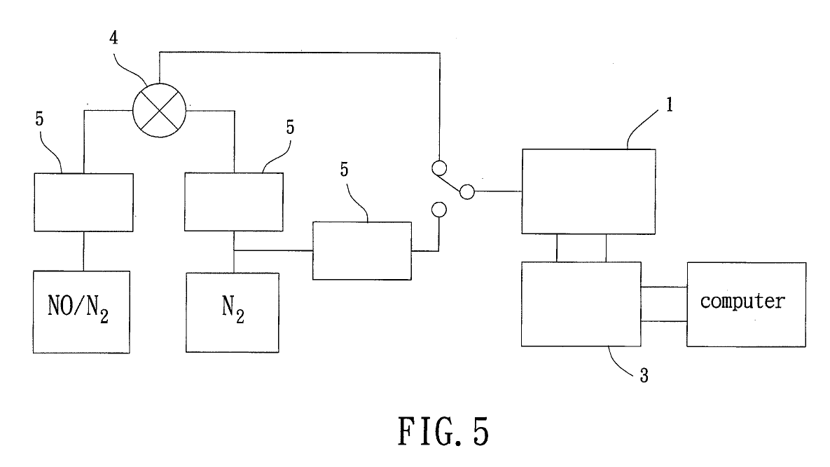

Referring to the FIG. 5, for further examining the function of the nitrogenous gas sensor 1 in the present invention, a complex detection program of nitrogenous gas is prepared, with pure nitrogen and nitric oxide delivered separately to a mixer 4 via two mass flow controllers 5 (MFC). The nitric oxide is diluted with the pure nitrogen in the mixer 4, and further adhered to the nitrogenous gas sensor 1 of the present invention. In the present embodiment, the complex detection program is preferably performed at around 24 to 30° C., and the flow rate of the MFC 5 is adjusted but not limited to 110 ml/min.

In the following test, a quantitative analysis of nitric oxide is operated at 28° C. through the complex detection program, in order to confirm the efficiency, reproducibility and sensitivity of the nitrogenous gas sensor 1 in the present invention.

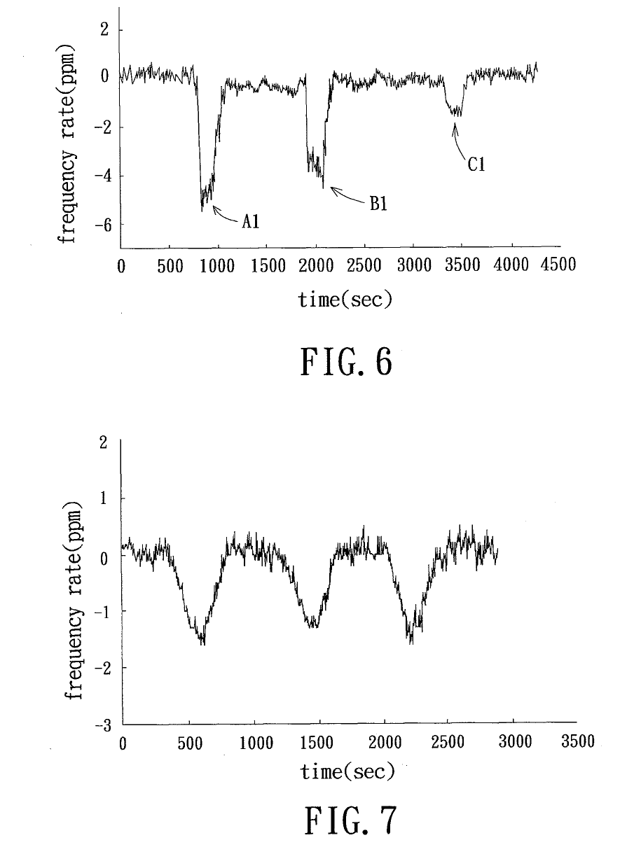

With reference to FIG. 6, a repeated on-off test is performed under 636, 592 and 479 ppb of nitric oxide individually in 5 minutes, wherein 4.8 (A1), 3.7(B1) and 1.6(C1) of the frequency rate are estimated at 636, 592 and 479 ppb of nitric oxide respectively. It is suggested that the nitrogenous gas sensor 1 of the present invention is highly effective and sensitive to the nitrogenous detection.

With reference to FIG. 7, another repeated on-off test is carried out under a circumstance of 342 ppb nitric oxide, wherein approximately 1.3 to 1.5 of the frequency rate is observed in the triple tests. It is suggested that the nitrogenous gas sensor 1 of the present invention clearly show reproducibility and accuracy on the nitrogenous detection.

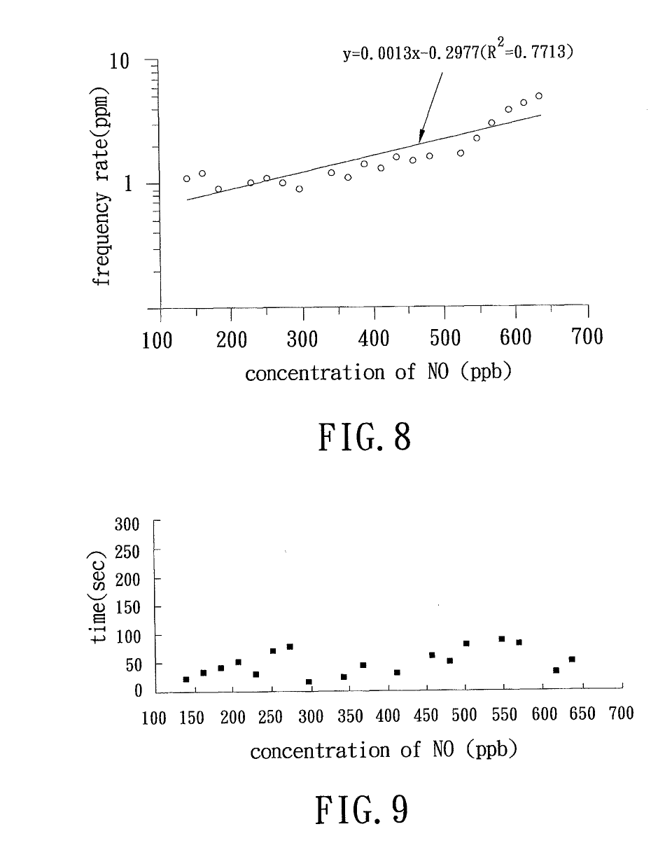

In FIG. 8, referring to a standard curve of the nitrogenous gas sensor in the present invention, it is suggested that the nitrogenous gas sensor of the present invention is highly sensitive to nitrogenous detection, wherein the FIG. 9 reveals a linear equation of y=0.0013x−0.2977 (R²=7713), with x, y standing for the concentration of nitric oxide and the frequency rate of the sensing layer. Hence, the limit of the nitrogenous gas sensor is about 23 ppb of nitric oxide.

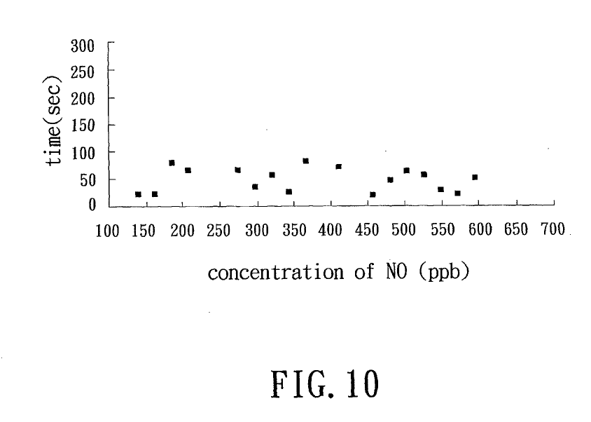

In FIGS. 9 and 10, referring to the response time and recovery time of the nitrogenous gas sensor in the present invention, it is suggested that nitrogenous gas sensor is sufficient to be effectively processed in a short time, with only 20 to 80 seconds of response time and the recovery time at room temperature.

Thus, with the arrangement of the sensing layer 14 consisting of a complex membrane of polyaniline and tungsten oxide, it is sufficient to enhance the machine strength, general tolerance, and contact surface with the target gases, which is significantly beneficial in advancing the sensitivity of the nitrogenous gas sensor in the present invention.

Furthermore, the complex membrane of the tungsten oxide and the polyaniline and the multi-porous structure of the polyaniline is adequate to improve the efficiency of the nitrogenous gas sensor in the present invention so that the nitrogenous detection can be achieved at room temperature in a shorter time.

Although the invention has been described in detail with reference to its presently preferred embodiment, it will be understood by one of ordinary skill in the art that various modifications can be made without departing from the spirit and the scope of the invention, as set forth in the appended claims.

What is claimed is:

1. A nitrogenous gas sensor, comprising:
a piezoelectricity plate which has a sensing surface;
two transducers placed on the sensing surface of the piezoelectricity plate for transduction of electrostatic potential energy and acoustic energy to generate surface acoustic waves on the piezoelectricity plate; and
a sensing layer installed on the sensing surface of the piezoelectricity plate between the two transducers, containing a complex materials of polyaniline and tungsten oxide.

2. The nitrogenous gas sensor as defined in claim 1, wherein the polyaniline reveals a multi-porous structure in the sensing layer, with the tungsten oxide stuffed into pores.

3. The nitrogenous gas sensor as defined in claim 1, wherein the volume ratio between the polyaniline and the tungsten oxide is 0.5˜3.

4. The nitrogenous gas sensor as defined in claim 1, wherein the nitrogenous gas sensor further comprises two acoustic reflectors installed on the sensing surface of the piezoelectric plate, adjacent to the two transducers respectively, with the two transducers sitting between the two acoustic reflectors and the sensing layer.

5. The nitrogenous gas sensor as defined in claim 1, wherein the two transducers are interdigitated transducers.

6. The nitrogenous gas sensor as defined in claim 1, wherein the two transducers are covered with a layer of polyimide.

7. A manufacturing method of the nitrogenous gas sensor, comprising:
a step of “manufacturing transducer,” by placing two transducers on a sensing surface of a piezoelectric plate; and
a step of “manufacturing sensing layer,” by mixing a solution of polyaniline and a solution of tungsten oxide to obtain a mixture of polyaniline and tungsten oxide, and further generating a sensing layer consisting of nano-scaled of complex polyaniline and tungsten oxide between the two transducer by dropping the mixture of polyaniline and tungsten oxide on the sensing surface of the piezoelectric plate.

8. The manufacturing method of the nitrogenous gas sensor as defined in claim 7, wherein the ratio between the solution of polyaniline and the solution of tungsten oxide is ≦2.5.

9. The manufacturing method of the nitrogenous gas sensor as defined in claim 7, wherein the manufacturing method further comprises a step of “gelling,” by processing an oxidization of tungsten hexachloride to obtain a gelatinous tungsten oxide.

10. The manufacturing method of the nitrogenous gas sensor as defined in claim 7, wherein the manufacturing method further comprises a step of “polymerization,” by processing an oxidative polymerization of aniline with an oxidant under an acidic circumstance to obtain a solution of polyaniline.
